(19) United States
(12) Patent Application Publication
(10) Pub. No.: US 2012/0258588 A1
(43) Pub. Date: Oct. 11, 2012

(54) SELF FORMING METAL FLUORIDE BARRIERS FOR FLUORINATED LOW-K DIELECTRICS

(76) Inventors: Christopher J. Jezewski, Hillsboro, OR (US); Daniel J. Zierath, Portland, OR (US); Florian Gstrein, Portland, OR (US)

(21) Appl. No.: 13/529,067

(22) Filed: Jun. 21, 2012

Related U.S. Application Data
(62) Division of application No. 12/426,131, filed on Apr. 17, 2009, now abandoned.

(51) Int. Cl. H01L 21/768

(52) U.S. Cl. 438/652; 257/E21.584

(57) ABSTRACT

A device and method of forming fluoride metal barriers at an interface of a fluorinated low-K dielectric and Cu or Cu alloy interconnects is disclosed. The fluoride metal barriers may prevent interconnects from reacting with the fluorinated low-K dielectric. The method may include depositing a thin film of metal or metal alloy on the fluorinated low-K dielectric. The thin film may include a metal or metal alloying element that reacts with free fluorine and/or fluorine compounds from the fluorinated low-K dielectric to form fluoride metal barriers.

### CROSS-REFERENCE TO RELATED PATENT APPLICATION

The present patent application is a divisional patent application of U.S. patent application Ser. No. 12/426,131, filed Mar. 31, 2009, the disclosure of which is incorporated by reference herein.

### BACKGROUND

In semiconductor manufacturing, the use of copper (Cu) for fabricating integrated circuits with multiple levels of interconnect lines and vias is becoming more common. Properties of Cu make it an attractive alternative to aluminum (Al). Typically, interlayer dielectrics (ILD) such as silicon dioxide may be used as insulation between Cu interconnects.

In a damascene process, the ILD is patterned with open trenches and vias for subsequent filling to form Cu interconnects. Via openings may be filled simultaneously with the trenches in a dual damascene process. In either case, Cu reactivity with ILDs can cause degradation in electrical yield, product yield, reliability and performance. For example, Cu is known to diffuse in oxides—which may cause device instability, or field induced breakdown issues. In addition, by itself, Cu shows poor adhesion to dielectrics due to the noble nature of the film. To prevent Cu diffusion into the ILD and to promote adhesion, a barrier metal layer is deposited on the ILD prior to filling the open trenches and vias. For example, the barrier metal layer may be formed of tantalum (Ta), tantalum nitride (TaN), tungsten (W), tungsten nitride (WN), titanium (Ti), and/or titanium nitride (TiN). When fluorinated ILDs are used, fluorine from the dielectric can lead to unfavorable reactions with the barrier layer negating the barrier layer effectiveness and consequently impacting reliability, yield and Cu adhesion.

### BRIEF DESCRIPTION OF THE DRAWINGS

The claimed subject matter will be understood more fully from the detailed description given below and from the accompanying drawings of disclosed embodiments which, however, should not be taken to limit the claimed subject matter to the specific embodiments described, but are for explanation and understanding only.

FIG. 1 is a cross-sectional view of a portion of an interconnect structure on a semiconductor device according to one embodiment.

FIG. 2 is a cross-sectional view of a portion of the interconnect structure of FIG. 1, shown after deposition of a liner.

FIG. 3 is a cross-sectional view of a portion of the interconnect structure of FIG. 2, shown after deposition of a capping layer.

FIG. 4 is a cross-sectional view of a portion of an interconnect structure of FIG. 3, shown after filling of one or more features.

FIG. 5 is a cross-sectional view of a portion of the interconnect structure of FIG. 4, shown after an annealing process.

FIG. 6 is a cross-sectional view of a portion of the interconnect structure of FIG. 5, shown after an optional planarization process.

FIG. 7 is a cross-sectional view of a portion of an interconnect structure on a semiconductor device according to one embodiment.

FIG. 8 is a cross-sectional view of a portion of an interconnect structure of FIG. 7, shown after an annealing process and an optional planarization process.

FIG. 9 is a cross-sectional view of a portion of an interconnect structure on a semiconductor device according to one embodiment, shown after an annealing process and an optional planarization process.

FIG. 10 is a flowchart of a method according to one embodiment.

### DETAILED DESCRIPTION

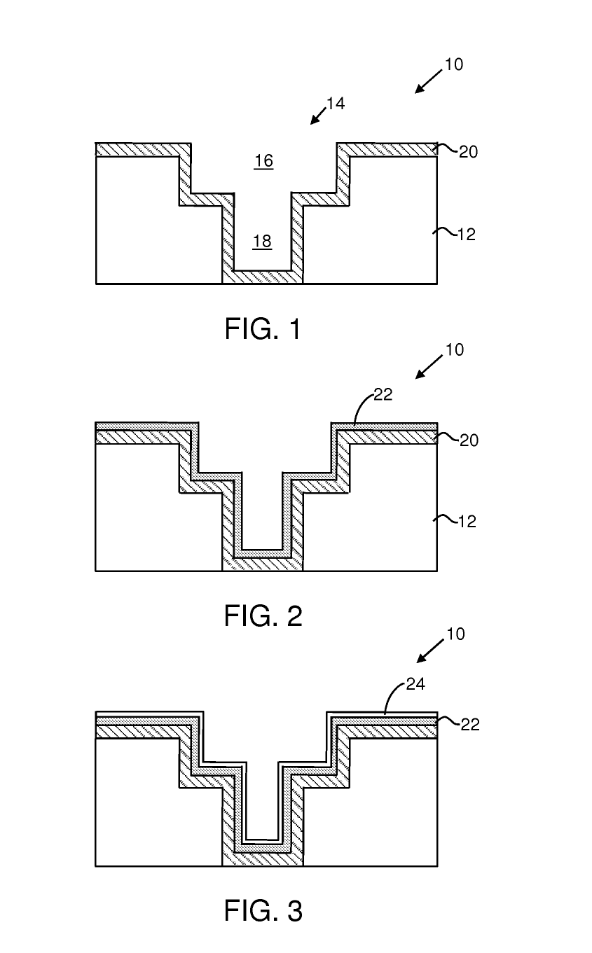

Referring to FIG. 1, a portion of an interconnect structure 10 on a semiconductor device according to one embodiment is shown. Interconnect structure 10 may include one of multiple layers of interconnects on the semiconductor device (not shown). Interconnect structure 10 may include a fluorinated low-K dielectric 12 formed on a substrate (not shown) of the semiconductor device. Fluorinated low-K dielectric 12 may be patterned, for example, such as by masking and etching processes, with one or more features 14 to allow space for interconnect formation. Feature 14 may include a trench 16, via opening 18, or other cavity for retaining interconnect material in forming interconnects.

In one embodiment, the fluorinated low-K dielectric 12 may have a small dielectric constant relative to silicon dioxide, which is typically used as a dielectric in semiconductor applications. Fluorinated low-K dielectric 12 may be used to replace silicon dioxide to reduce parasitic capacitance, thus enabling faster switching speeds and lower heat dissipation. Non-limiting examples of fluorinated low-K dielectric 12 include polytetrafluoroethylene (PTFE) also commonly known as Teflon® and available from E. I. du Pont de Nemours and Company of Wilmington, Delaware, fluorinated ultra-low-K dielectrics (ULK), and other fluoropolymers, but the claimed subject matter is not limited in this regard.

According to one embodiment, a layer of metal or metal alloy 20 may be deposited on top of the fluorinated low-K dielectric 12 on interconnect structure 10 as shown in FIG. 1. As used herein, reference to depositing on top of the fluorinated low-K dielectric 12 and/or other layer(s) also includes lining the walls and/or bottom of the trenches 16 and/or via openings 18 with the deposited material.

The layer of metal or metal alloy 20 may also be referred to herein as “thin film”. The thin film 20 may be deposited using a deposition technique, such as, but not limited to, physical vapor deposition (PVD), atomic layer deposition (ALD), chemical vapor deposition (CVD), electroless, or electroplating.

Conventional metal barriers typically are attacked by fluorine from a fluorinated dielectric and become brittle or volatile. In one embodiment, the metal or metal alloy of thin film 20 may be selected to react with the fluorinated low-K dielectric 12 to form an adhesion layer and/or a diffusion barrier, as further described below. In one embodiment, the free fluorine and/or fluorine compounds of the fluorinated low-K dielectric 12 may be mobile enough to interact with the metal or metal alloy of thin film 20 at or near room temperature and/or prior to an annealing process such as described below.

Referring to FIG. 2, interconnect structure 10 may include a layer of tantalum (Ta), titanium (Ti), tungsten (W), ruthenium (Ru), cobalt (Co), their nitrides or carbides, or combinations thereof 22 deposited on top of the thin film 20. Since the layer 22 may provide a liner to an interconnect material, as shown and described below, the layer 22 is herein referred to as “liner”. The liner 22 may serve as a nucleation substrate for the interconnect material. The liner 22 may also improve wetting to a next layer, such as shown in FIG. 3.

With reference to FIG. 3, interconnect structure 10 may include a capping layer of pure or nearly pure Cu 24 deposited on top of the liner 22 to protect the liner 22 and/or a subsequently formed metal fluoride barrier, as shown and described below. In one embodiment, the capping layer 24 may comprise other metals or alloys. The capping layer 24 may be deposited using PVD, ALD, CVD, electroless, or electroplating techniques.

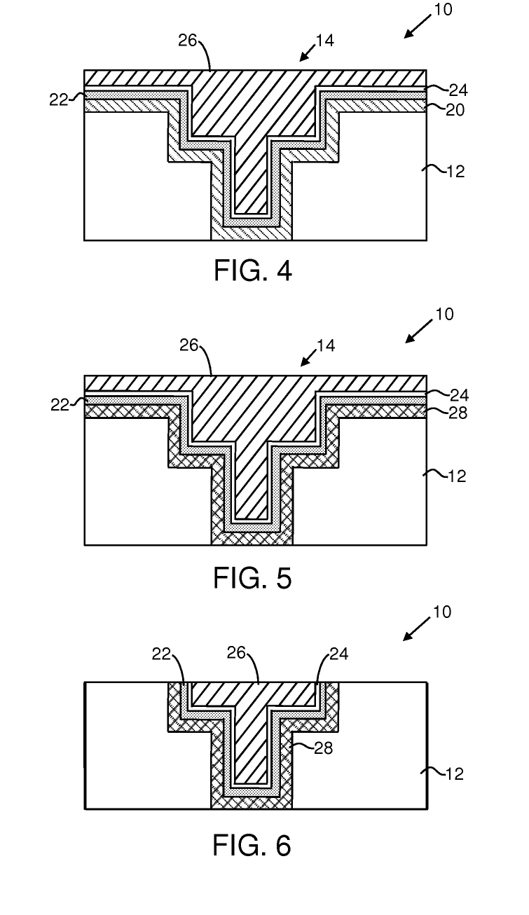

Referring to FIG. 4, interconnect structure 10 may include an interconnect material 26 filled in one or more features 14 of the fluorinated low-K dielectric 12 to form one or more interconnects. In one embodiment, the interconnect material 26 is conductive and may comprise Cu or Cu alloy. The interconnect material 26 may be filled using PVD, ALD, CVD, electroless, and electroplating deposition processes.

The interconnect material 26 may be deposited on top of the capping layer 24. Interconnect material 26 may be separated from the fluorinated low-K dielectric 12 by one or more of the layers 20, 22, 24. Particularly, a self formed fluoride metal barrier 22 may shield interconnect material 26 from free fluorine and/or fluorine compounds from fluorinated low-K dielectric 12.

Referring to FIG. 5, interconnect structure 10 is shown after an annealing process. The thin film 20 may react with the fluorinated low-K dielectric 12 and form a metal fluoride barrier 28. The metal fluoride barrier 28 may be chemically and thermally stable. The annealing process may include heating the substrate to a predetermined temperature and may include any annealing schemes that allow interlayer reactions to occur.

More specifically, the metal or alloying element of the metal alloy of thin film 20 may react with free fluorine and/or fluorine compounds from the fluorinated low-K dielectric 12 and form metal fluoride barrier 28. The metal fluoride barrier 28 may prevent or at least significantly reduce interaction between the fluorinated low-K dielectric 12 and interconnect material 26. In one embodiment, without metal fluoride barrier 28, the liner 22 would be exposed to free fluorine and/or fluorine compounds and form volatile metal fluorides. This may negatively impact filling of the interconnect material 26 in the fluorinated low-K dielectric 12 and the reliability of the resulting interconnects.

Metal fluoride barrier 28 may be considered a self forming barrier due to the ability of the thin film 20 and the fluorinated low-K dielectric 12 to react before, during, and/or after the annealing process to form the metal fluoride barrier 22 at the interface between the interconnect material 26 and the fluorinated low-K dielectric 12. In one embodiment, the thin film 20 is replaced by metal fluoride barrier 28 as shown in FIG. 5. It is noted that reactions may occur until the free fluorine and/or fluorine compounds from the fluorinated low-K dielectric 12 are exhausted or no longer come in contact with the thin film 20, and thus the fluorinated low-K dielectric 12 is considered to be stabilized. In one embodiment, the entire thin film 20 may not have reacted with the fluorine and/or fluorine compounds therefore a residual thin film may remain on top of the portion that has reacted, that is, the metal fluoride barrier 22. For example, the residual thin film is sandwiched between the metal fluoride barrier 28 and the liner 22.

In one embodiment, the metal or alloying element of the metal alloy of the thin film 20 may react with free fluorine and/or fluorine compounds from the fluorinated low-K dielectric 12 to form stable metal fluorides suitable for existing as a barrier, as mentioned above. The metal or alloying component of the metal alloy may include aluminum (Al), zinc (Zn), iron (Fe), cobalt (Co), nickel (Ni), zirconium (Zr), yttrium (Y), and/or hafnium (Hf). Other elements may also be suitable for forming metal fluorides. For example, metal fluorides such as CoF₂, CoF₃, CoF₄, NiF₂, AlF₃, YF₃, ZrF₄, and HfF₄ may be formed and used as a metal fluoride barrier. However, the claimed subject matter is not limited to these compounds.

In one embodiment, the thin film comprises CuAl. Since Al has a greater affinity for fluorine compared to Cu and has the ability to form a stable fluoride such as AlF₃, CuAl may be an attractive metal alloy in the manufacturing of a self forming metal fluoride barrier. In addition, AlF₃ as a metal fluoride barrier includes characteristics that may be desirable. Some of these characteristics may include not being affected by water, good mechanical strength, low dielectric constant (low-K), and good adherence to the fluorinated low-K dielectric.

Referring now to FIG. 6, interconnect structure 10 may undergo a planarization process for removal of excess material. For example, chemical-mechanical polishing (CMP) or electropolishing may be used to remove portions of interconnect material 26 from the top of interconnect structure 10. The planarization process may also remove portions of capping layer 24, liner 22, and/or metal fluoride barrier 28 from the top of the fluorinated low-K dielectric 12. As shown in FIG. 6, capping layer 24, liner 22, metal fluoride barrier 28, and interconnect material 26 are within the features 14 and distinct interconnect lines and/or vias are formed.

With reference to FIG. 7, a portion of an interconnect structure 30 on a substrate of a semiconductor device is shown according to one embodiment. Interconnect structure 30 includes a thin film of metal or metal alloy 32 deposited on top of a patterned fluorinated low-K dielectric 34 identical to or at least similar to what is shown in FIG. 1. Interconnect structure 30 may further include a capping layer of pure or nearly pure Cu 36 deposited on top of the thin film 32 to protect a subsequently formed metal fluoride barrier. Interconnect structure 30 may include one or more features 38 that may be filled by interconnect material to form interconnect lines and/or vias.

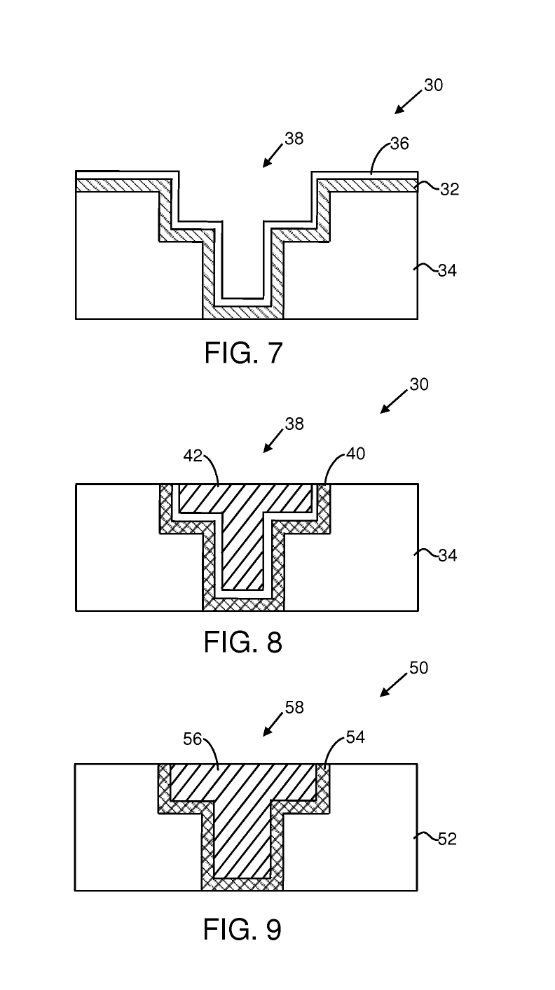

In FIG. 8, interconnect structure 30 shows FIG. 7 after an annealing process and an optional planarization process. Similar to FIG. 5 and FIG. 6, interconnect structure 30 undergoes an annealing process that causes interaction between the thin film 32 and the patterned fluorinated low-K dielectric 34, resulting in a self formed metal fluoride barrier 40. Interconnect structure 30 further includes interconnect lines and/or vias 42 formed by using PVD, ALD, CVD, electroless, or electroplating techniques.

Referring to FIG. 9, a portion of an interconnect structure 50 on a substrate of a semiconductor device is shown according to one embodiment, shown after an annealing process and an optional planarization process. Interconnect structure 50 includes a thin film of metal or metal alloy (not shown) previously deposited on top of a patterned fluorinated low-K dielectric 52 identical to or at least similar to what is shown in FIG. 1. The thin film and the fluorinated low-K dielectric 52 have reacted to form a metal fluoride barrier 54. An interconnect 56 is formed in the features 58 patterned on the fluorinated low-K dielectric 52 using PVD, ALD, CVD, electroless, or electroplating techniques. In this embodiment, since the thin film acts as a precursor of the metal fluoride barrier 54, no additional layers are deposited and thus may extend a gap fill window. In one embodiment, interconnect resistance may be reduced due to the metal fluoride barrier 54 being formed directly in contact with the fluorinated low-K dielectric 52.

An experiment was performed to evaluate the stability of the fluorinated low-K dielectric. In accordance with one embodiment, a thin film of CuAl was deposited on top of a patterned fluorinated low-K dielectric. A layer of Ta was deposited on top of the thin film of CuAl and a hammer test anneal at 400 degrees C. for 2 hours was conducted. After the hammer test anneal, no delamination as a result of volatile Ta fluoride formation was observed and there was no Cu, Al, or Ta found in the fluorinated low-K dielectric. The results validate the feasibility of the self forming metal fluoride barrier AlF₃ as a barrier between a Cu or Cu alloy interconnect and the fluorinated low-K dielectric.

In the embodiments as shown in FIGS. 1-9, the interconnect structures 10, 30, and 50 are shown using a dual damascene technique in which a trench and via opening are filled simultaneously to form interconnect lines and vias, respectively. It should be known that the claimed subject matter is not limited as such and a trench and/or via opening may be separately filled. Although shown in all of the figures above with a via opening having a bottom in which one or more layers are deposited on top, the claimed subject matter is not limited in this regard and may include bottomless features. Further, the features and layers as shown in the figures are for illustrative purposes only and are not drawn to scale.

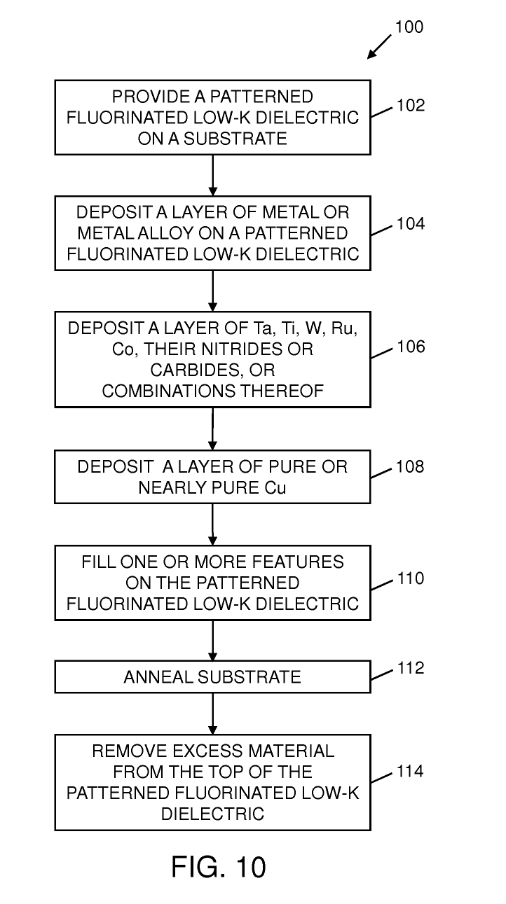

Turning to FIG. 10, a method 100 of fabricating an interconnect structure in a semiconductor device is shown according to one embodiment. At 102, method 100 may include providing a patterned fluorinated low-K dielectric on an interconnect structure on a substrate of a semiconductor device. At 104, method 100 may include depositing a layer of metal or metal alloy on the patterned fluorinated low-K dielectric. The metal or alloying element of the metal alloy may include Al, Zn, Fe, Co, Ni, Zr, Y, and/or Hf. At 106, method 100 may include depositing a layer of Ta, Ti, W, Ru, Co, their nitrides or carbides, or combinations thereof, herein referred to as “liner”. The liner may be deposited on top of the layer of metal or metal alloy or on top of a metal fluoride barrier, as further described below.

Method 100 may include depositing a layer of pure or nearly pure Cu as a capping layer at block 108. In one or more embodiments, the layer of pure or nearly pure Cu may be deposited on top of the liner, on top of the layer of metal or metal alloy, or on top of a metal fluoride barrier, as further described below. At 110, method 100 may include filling one or more features patterned on the fluorinated low-K dielectric with an interconnect material, such as Cu or Cu alloy. Method 100 may include annealing the substrate at block 112. Method 100 may further include planarizing one or more of the above-mentioned layers and/or the interconnect material at block 114.

It is noted that various blocks may be modified, added, or removed depending on a specific application or implementation while still remaining within the scope of the claimed subject matter. Further, in one or more embodiments, the blocks of method 100 are not limited to the order in which method 100 is presented.

For example, regarding block 112, annealing may be performed one or more times immediately after thin film deposition, after deposition of an additional layer, or reserved until another process in backend interconnect processing. Specifically, in one embodiment, the annealing process may occur prior to filling one or more features of the patterned fluorinated low-K dielectric. In one embodiment, the annealing process may occur immediately after depositing a layer of metal or metal alloy on a patterned fluorinated low-K dielectric (104). Therefore, with reference to one or more of the above-described depositing blocks 106 and/or 108, depositing of the layer(s) may be on top of a metal fluoride barrier formed from the layer of metal or metal alloy and the fluorinated low-K dielectric. In one embodiment, as mentioned above, the metal fluoride barrier may form or begin to form upon depositing a layer of metal or metal alloy 104 prior to the annealing process.

In other examples, in an embodiment without a liner, block 106 is omitted. In an embodiment without a capping layer, block 108 is omitted. Further, one or more of the above-described embodiments may be repeated to form multiple levels of interconnect structures within the semiconductor device.

It is appreciated that self forming metal fluoride barriers for fluorinated low-K dielectrics has been explained with reference to one or more embodiments, and that the claimed subject matter is not limited to the specific details given above. References in the specification made to other embodiments fall within the scope of the claimed subject matter.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the claimed subject matter. The various appearances of “an embodiment,” “one embodiment,” or “some embodiments” are not necessarily all referring to the same embodiments.

If the specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Those skilled in the art having the benefit of this disclosure will appreciate that many other variations from the foregoing description and drawings may be made within the scope of the claimed subject matter. Indeed, the claimed subject matter is not limited to the details described above. Rather, it is the following claims including any amendments thereto that define such scope and variations.

1. A method comprising:
depositing a thin film of metal or metal alloy on top of a fluorinated low-K dielectric on a substrate; and
filling one or more features patterned on the fluorinated low-K dielectric to form one or more interconnects,
wherein a metal fluoride barrier forms from interaction between the thin film and the fluorinated low-K dielectric, and further wherein the metal fluoride barrier is capable of preventing interaction between said one or more interconnects and the fluorinated low-K dielectric.

2. The method of claim 1, wherein the thin film comprises at least a metal or alloying element of the metal alloy selected from the group comprising Al, Zn, Fe, Co, Ni, Zr, Y, or Hf, or combinations thereof.

3. The method of claim 1, wherein the thin film comprises CuAl.

4. The method of claim 1, wherein the metal fluoride barrier is chemically and thermally stable.

5. The method of claim 1, wherein the metal fluoride barrier comprises AlF₃.

6. The method of claim 1, further comprising depositing a pure or nearly pure Cu capping layer on top of the thin film.

7. The method of claim 1, further comprising forming a liner by depositing a layer of Ta, Ti, W, Ru, Co, their nitrides or carbides, or combinations thereof on top of the metal fluoride barrier.

8. The method of claim 7, further comprising depositing a pure or nearly pure Cu capping layer on top of the liner.

9. The method of claim 1, further comprising forming a liner by depositing a layer of Ta, Ti, W, Ru, Co, their nitrides or carbides, or combinations thereof on top of the thin film.

10. The method of claim 9, further comprising depositing a pure or nearly pure Cu capping layer on top of the liner.

11. The method of claim 1, further comprising annealing the substrate.

12. A method comprising:
providing a patterned fluorinated low-K dielectric on a substrate;
depositing a layer of metal or metal alloy on the patterned fluorinated low-K dielectric;
filling at least a trench or via of the patterned fluorinated low-K dielectric with Cu or Cu alloy to form one or more interconnects; and
annealing the layer of metal or metal alloy and the patterned fluorinated low-K dielectric, wherein said annealing causes self formation of a metal fluoride barrier at an interface between said one or more interconnects and the patterned fluorinated low-K dielectric.

13. The method of claim 12, wherein the layer of metal or metal alloy comprises one or more elements selected from the group comprising Al, Zn, Fe, Co, Ni, Zr, Y, or Hf, or combinations thereof.

14. The method of claim 12, further comprising depositing a layer of pure or nearly pure Cu on top of the layer of metal or metal alloy.

15. The method of claim 12, further comprising depositing a layer of Ta, Ti, W, Ru, Co, their nitrides or carbides, or combinations thereof on top of the layer of metal or metal alloy.

16-20. (canceled)
